(19) United States
(12) Patent Application Publication
(10) Pub. No.: US 2021/0035707 A1
(43) Pub. Date: Feb. 4, 2021

(54) CABLE ASSEMBLY

(71) Applicant: James Cheng Lee, La Habra, CA (US)

(72) Inventor: James Cheng Lee, La Habra, CA (US)

(21) Appl. No.: 16/855,203

(22) Filed: Apr. 22, 2020

(30) Foreign Application Priority Data
Aug. 2, 2019 (CN) 201921253109.0

(51) Int. Cl. H01B 7/00; H01R 12/53; H05K 1/18; H05K 1/11; H05K 1/02

(52) U.S. Cl. CPC H01B 7/0009; H01R 12/53; H05K 2201/10356; H05K 1/111; H05K 1/0203; H05K 1/181

(57) ABSTRACT

A cable assembly includes an insulating housing, a center plate fastened in the insulating housing, and a terminal assembly fastened in the insulating housing. The center plate has a base plate. Rears of two opposite sides of the base plate are connected with two connecting feet. A pair of the bending arms are connected with the rears of the two opposite sides of the base plate. The pair of the bending arms have two bending portions, two extending arms and two hooking portions. The two extending arms include two first extending portions, two connecting portions and two second extending portions. The two hooking portions have two first bending feet, two second bending feet and two third bending feet. The two connecting portions and the two second extending portions are exposed out of the insulating housing. The two first bending feet are exposed out of the insulating housing.

### CROSS-REFERENCE TO RELATED APPLICATION

The present application is based on, and claims priority from, China Patent Application No. 201921253109.0, filed Aug. 2, 2019, the disclosure of which is hereby incorporated by reference herein in its entirety.

### BACKGROUND OF THE INVENTION

### 1. Field of the Invention

The present invention generally relates to a cable assembly, and more particularly to a cable assembly having a cable stress lowering function.

### 2. The Related Art

A cable assembly is used for connecting with two electronic devices for transmitting data. Because a current electronic device generates a larger and larger data quantity, a transmission speed of the cable assembly must be correspondingly promoted, a high-speed transmission cable of the cable assembly generally has a larger wire diameter.

However, a larger mechanical stress generated under a larger wire diameter of the high-speed transmission cable will cause the high-speed transmission cable easily fall off at the time of the high-speed transmission cable being soldered to a circuit board. As a result, an assembling reliability degree is caused to be poorer.

Thus, it is essential to provide an innovative cable assembly having a cable stress lowering function.

### SUMMARY OF THE INVENTION

An object of the present invention is to provide a cable assembly. The cable assembly includes a cable and a circuit board. The cable includes a plurality of first wire cores and a plurality of second wire cores. Each first wire core has a first conductor. Each second wire core has a second conductor. The circuit board is disposed to and connected with one end of the cable. A surface of the circuit board is equipped with a plurality of first soldering pads transversely arranged in one row, and a plurality of second soldering pads transversely arranged in one row and located in front of the plurality of the first soldering pads, so the plurality of the first soldering pads and the plurality of the second soldering pads of the surface of the circuit board are arranged in two rows. A distance between the plurality of the first soldering pads of the circuit board and a tail end of the circuit board is shorter than a distance between the plurality of the second soldering pads of the circuit board and the tail end of the circuit board. The first conductors of the plurality of the first wire cores are arranged in two rows along a thickness direction of the circuit board, and the second conductors of the plurality of the second wire cores are arranged in two rows along the thickness direction of the circuit board. The first conductors of the plurality of the first wire cores are connected to the plurality of the first soldering pads of the surface of the circuit board. The second conductors of the plurality of the second wire cores are connected to the plurality of the second soldering pads of the surface of the circuit board. The surface of the circuit board has a board thickness compensation structure. The plurality of the second soldering pads of the surface of the circuit board are disposed to a surface of the board thickness compensation structure. Positions of the plurality of the second soldering pads of the surface of the circuit board are disposed beyond positions of the plurality of the first soldering pads of the surface of the circuit board, so positions of the plurality of the second wire cores connected to the surface of the circuit board are located beyond positions of the plurality of the first wire cores connected to the surface of the circuit board.

Another object of the present invention is to provide a cable assembly. The cable assembly includes a cable and a circuit board. The cable includes a plurality of first wire cores and a plurality of second wire cores. Each first wire core has a first conductor. Each second wire core has a second conductor. The circuit board is disposed to and connected with one end of the cable. A surface of the circuit board is equipped with a plurality of first soldering pads transversely arranged in one row, and a plurality of second soldering pads transversely arranged in one row, so the plurality of the first soldering pads and the plurality of the second soldering pads of the surface of the circuit board are arranged in two rows. A distance between the plurality of the first soldering pads of the circuit board and a tail end of the circuit board is shorter than a distance between the plurality of the second soldering pads of the circuit board and the tail end of the circuit board. The first conductors of the plurality of the first wire cores are arranged in two rows along a thickness direction of the circuit board, and the second conductors of the plurality of the second wire cores are arranged in two rows along the thickness direction of the circuit board. The first conductors of the plurality of the first wire cores are connected to the plurality of the first soldering pads of the surface of the circuit board, the second conductors of the plurality of the second wire cores are connected to the plurality of the second soldering pads of the surface of the circuit board. The circuit board has a board thickness compensation structure. The plurality of the first soldering pads of the surface of the circuit board are disposed to a surface of the board thickness compensation structure. Positions of the plurality of the second soldering pads of the surface of the circuit board are disposed beyond positions of the plurality of the first soldering pads of the surface of the circuit board, so positions of the plurality of the second wire cores connected to the surface of the circuit board are located beyond positions of the plurality of the first wire cores connected to the surface of the circuit board.

Another object of the present invention is to provide a cable assembly. The cable assembly includes a cable, a circuit board, a heat dissipating module and an outer cover. The cable includes a plurality of first wire cores and a plurality of second wire cores. Each first wire core has a first conductor. Each second wire core has a second conductor. The circuit board is connected with one end of the cable. A surface of the circuit board is equipped with a plurality of first soldering pads transversely arranged in one row, and a plurality of second soldering pads transversely arranged in one row and located in front of the plurality of the first soldering pads, so the plurality of the first soldering pads and the plurality of the second soldering pads of the surface of the circuit board are arranged in two rows. The first conductors of the plurality of the first wire cores are arranged in two rows along a thickness direction of the circuit board, and the second conductors of the plurality of the second wire cores are arranged in two rows along the thickness direction of the circuit board. The first conductors of the plurality of the first wire cores are soldered to the plurality of the first soldering pads of the surface of the circuit board, the second conductors of the plurality of the second wire cores are soldered to the plurality of the second soldering pads of the surface of the circuit board. The surface of the circuit board has a board thickness compensation structure. The plurality of the second soldering pads of the surface of the circuit board are disposed to the surface of the board thickness compensation structure, or the plurality of the first soldering pads of the surface of the circuit board are disposed to the surface of the board thickness compensation structure to make positions of the plurality of the second soldering pads of the surface of the circuit board beyond positions of the plurality of the first soldering pads of the surface of the circuit board, so positions of the plurality of the second wire cores connected to the surface of the circuit board are located beyond positions of the plurality of the first wire cores connected to the surface of the circuit board. The heat dissipating module is disposed on the circuit board. The outer cover surrounds the circuit board, the heat dissipating module and the cable.

As described above, the cable assembly eliminates a stress of the core wire group being soldered to the circuit board by virtue of the plurality of the board thickness compensation structures and the plurality of the board thickness compensation structures, so that the plurality of the second soldering pads of the board thickness compensation structure is prevented from peeling off, and the plurality of the first soldering pads of the board thickness compensation structure are prevented from peeling off, so the cable assembly is capable of effectively lowering a mechanical stress of the circuit board, and the circuit board of the cable assembly has a lower mechanical stress. As a result, the cable assembly has a cable stress lowering function.

### BRIEF DESCRIPTION OF THE DRAWINGS

The present invention will be apparent to those skilled in the art by reading the following description, with reference to the attached drawings, in which:

FIG. 1 is a perspective view of a cable assembly in accordance with a first preferred embodiment of the present invention;

FIG. 2 is an exploded view of the cable assembly of FIG. 1;

FIG. 3 is a perspective view of an upper cover of the cable assembly of FIG. 2;

FIG. 4 is a sectional view of the cable assembly along a line IV-IV of FIG. 1;

FIG. 5 is a partially enlarged view of an encircled portion V of the cable assembly of FIG. 4; and

FIG. 6 is a diagrammatic drawing of the cable assembly in accordance with a second preferred embodiment of the present invention.

### DETAILED DESCRIPTION OF THE PREFERRED EMBODIMENT

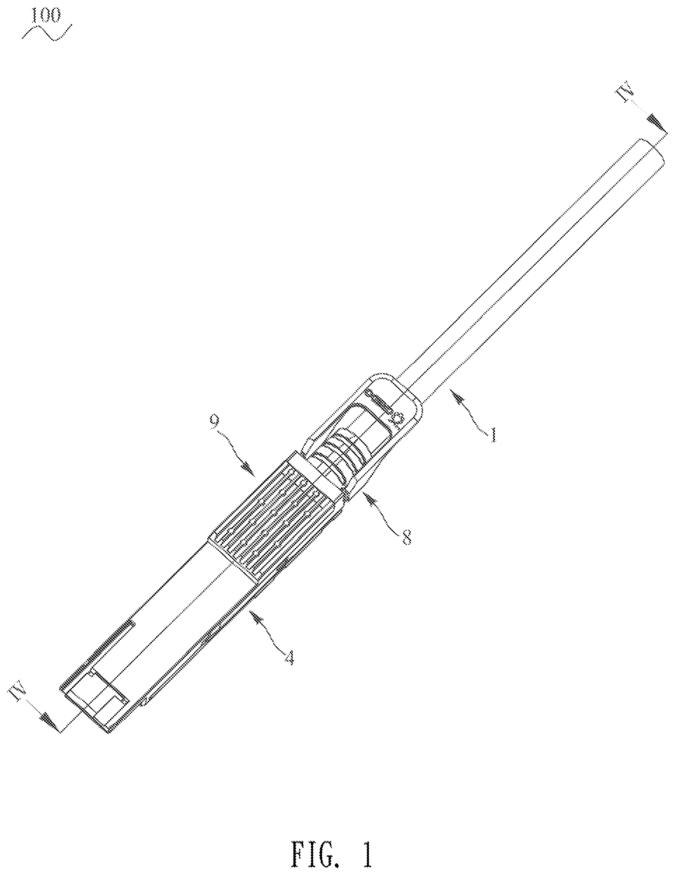

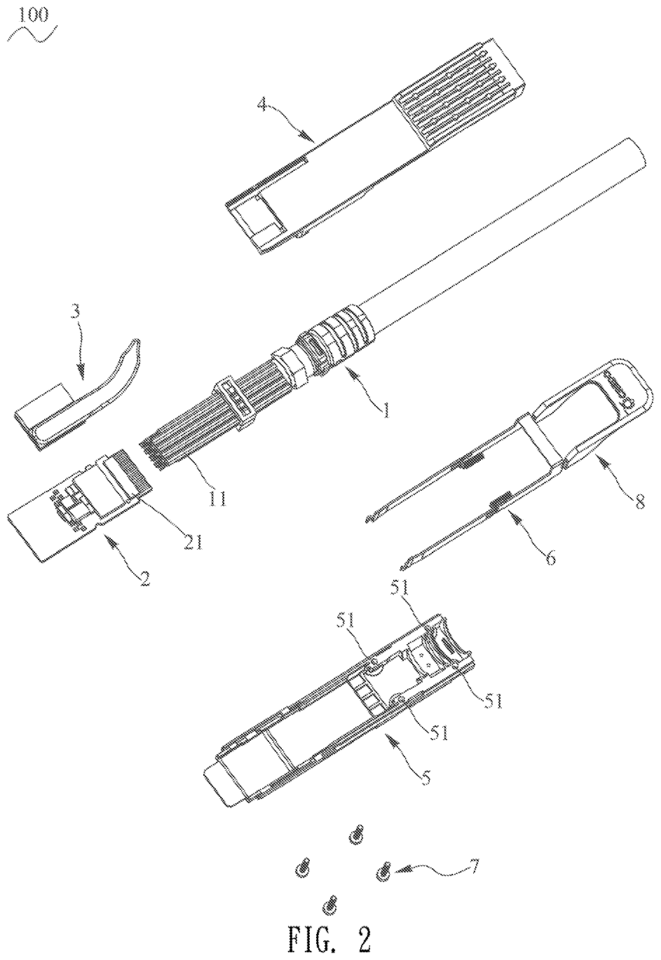

With reference to FIG. 1 and FIG. 2, a cable assembly 100 in accordance with a first preferred embodiment of the present invention is shown. The cable assembly 100 includes a cable 1, a circuit board 2, a heat dissipating module 3, an outer cover 9, a bolt-lock assembly 6, a plurality of screws 7 and a pulling ring 8. The outer cover 9 includes an upper cover 4 and a lower cover 5. The outer cover 9 surrounds the circuit board 2, the heat dissipating module 3 and the cable 1.

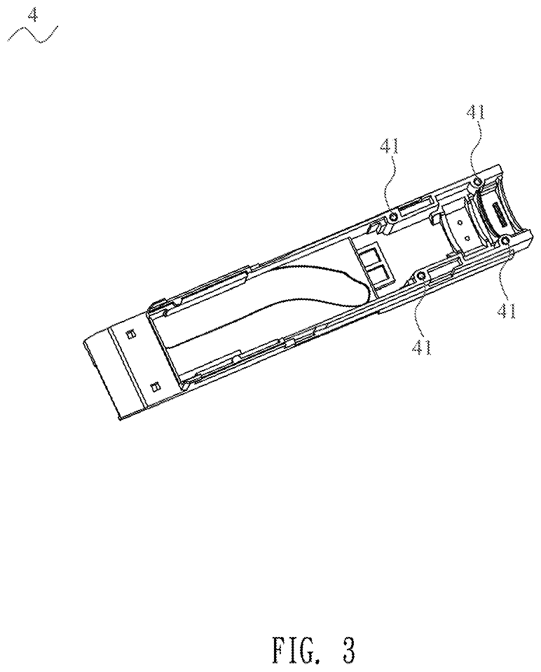

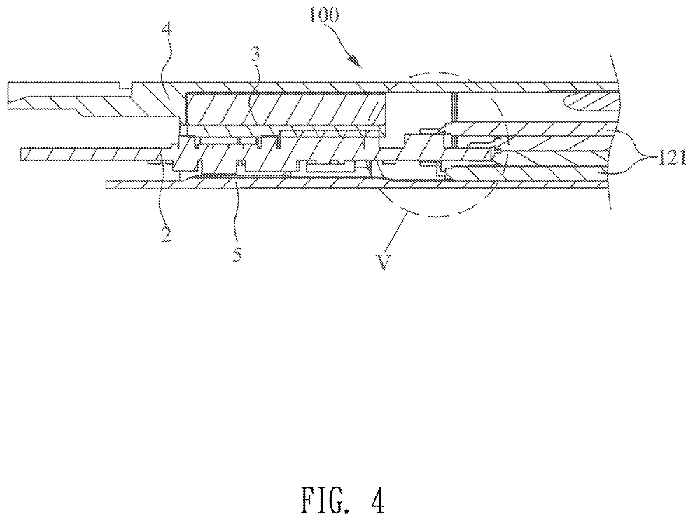

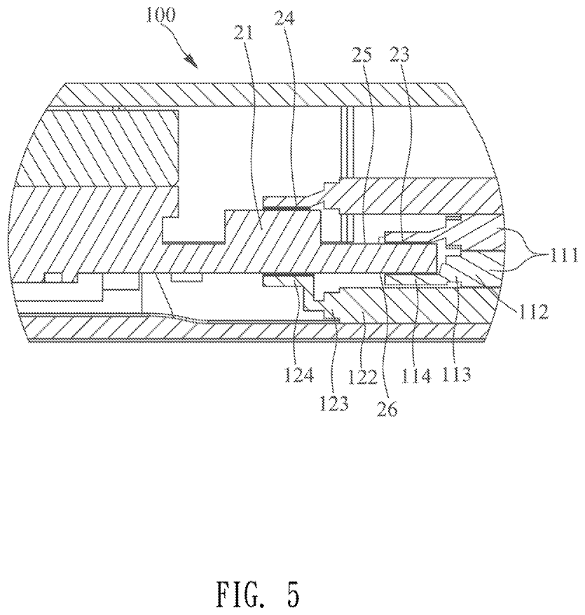

Referring to FIG. 1 to FIG. 5, the circuit board 2 has a top surface 25, and a bottom surface 26 opposite to the top surface 25. A front end of the cable 1 is soldered to the top surface 25 and the bottom surface 26 of the circuit board 2. The heat dissipating module 3 is disposed on the circuit board 2. The upper cover 4 is disposed to a top of the heat dissipating module 3. The lower cover 5 is disposed under the circuit board 2. The upper cover 4 is covered to the lower cover 5 to form the outer cover 9. The bolt-lock assembly 6 is assembled to and buckled to two sides of the outer cover 9. The bolt-lock assembly 6 is assembled to and buckled to two sides of the upper cover 4, and two sides of the lower cover 5 located under the upper cover 4. A rear end of the bolt-lock assembly 6 is connected with the pulling ring 8. Rears of the two sides of the lower cover 5 opens a plurality of lower fastening holes 51 penetrating through a top surface and a bottom surface of the lower cover 5. Rears of the two sides of the upper cover 4 open a plurality of upper fastening holes 41 penetrating through a bottom surface of the upper cover 4. The plurality of the screws 7 are fastened in the plurality of the lower fastening holes 51 and the plurality of the upper fastening holes 41 so as to fasten the lower cover 5 to the upper cover 4.

Referring to FIG. 1 to FIG. 5, the cable 1 includes a core wire group 11. The core wire group 11 includes a plurality of first wire cores 111 and a plurality of second wire cores 121. Each first wire core 111 has a first covering body 112, a first insulating body 113 and a first conductor 114. The first insulating body 113 surrounds the first conductor 114. The first covering body 112 surrounds the first insulating body 113 together with the first conductor 114. The first covering body 112 is used for protecting own structures of the plurality of the first wire cores 111. The first insulating body 113 projects beyond a front end of the first covering body 112. The first insulating body 113 is used for ensuring a normal transmission function of the first conductor 114. The first conductor 114 projects beyond a front end of the first insulating body 113. The first conductor 114 is used for conducting electric power and signals.

Each second wire core 121 has a second covering body 122, a second insulating body 123 and a second conductor 124. The second insulating body 123 surrounds the second conductor 124. The second covering body 122 surrounds the second insulating body 123 and the second conductor 124. The second covering body 122 is used for protecting own structures of the plurality of second wire cores 121. The second insulating body 123 projects beyond a front end of the second covering body 122. The second insulating body 123 is used for ensuring a normal transmission function of the second conductor 124. The second conductor 124 projects beyond a front end of the second insulating body 123. The second conductor 124 is used for transmitting the electric power and the signals.

A rear end of a surface of the circuit board 2 is equipped with a plurality of first soldering pads 23 transversely arranged in one row, and a plurality of second soldering pads 24 transversely arranged in one row and located in front of the plurality of first soldering pads 23, so the plurality of the first soldering pads 23 and the plurality of the second soldering pads 24 of the rear end of the surface of the circuit board 2 are arranged in two rows. A distance between the plurality of the first soldering pads 23 of the surface of the circuit board 2 and a tail end of the circuit board 2 is shorter than a distance between the plurality of the second soldering pads 24 of the surface of the circuit board 2 and the tail end of the circuit board 2. The first conductors 114 of the plurality of the first wire cores 111 are arranged in two rows along a thickness direction of the circuit board 2, and the second conductors 124 of the plurality of the second wire cores 121 are arranged in two rows along the thickness direction of the circuit board 2. The first conductors 114 of the plurality of the first wire cores 111 are soldered to and connected to the plurality of the first soldering pads 23 of the surface of the circuit board 2. The second conductors 124 of the plurality of the second wire cores 121 are soldered to and connected to the plurality of the second soldering pads 24 of the surface of the circuit board 2. The surface of the circuit board 2 has a board thickness compensation structure 21, the plurality of the second soldering pads 24 of the surface of the circuit board 2 are disposed to a surface of the board thickness compensation structure 21. The board thickness compensation structure 21 is protruded from and projects beyond the surface of the circuit board 2. Positions of the plurality of the second soldering pads 24 of the surface of the circuit board 2 are disposed beyond positions of the plurality of the first soldering pads 23 of the surface of the circuit board 2, so positions of the plurality of the second wire cores 121 connected to the surface of the circuit board 2 are located beyond positions of the plurality of the first wire cores 111 connected to the surface of the circuit board 2.

The surface of the circuit board 2 is one of the top surface 25 and the bottom surface 26 of the circuit board 2. A rear end of the circuit board 2 is equipped with the plurality of first soldering pads 23 and the plurality of second soldering pads 24. Rear ends of the top surface 25 and the bottom surface 26 of the circuit board 2 are equipped with the plurality of the first soldering pads 23 and the plurality of the second soldering pads 24. Specifically, a rear end of the top surface 25 of the circuit board 2 is equipped with the plurality of first soldering pads 23 and the plurality of second soldering pads 24. In the first preferred embodiment, the plurality of the first soldering pads 23 and the plurality of the second soldering pads 24 of the top surface 25 of the circuit board 2 are disposed along a front-to-rear direction and disposed in two rows. The plurality of the first soldering pads 23 of the top surface 25 of the circuit board 2 are disposed behind the plurality of the second soldering pads 24 of the top surface 25 of the circuit board 2. A distance between the plurality of the first soldering pads 23 of the top surface 25 of the circuit board 2 and the tail end of the circuit board 2 is shorter than a distance between the plurality of the second soldering pads 24 of the top surface 25 of the circuit board 2 and the tail end of the circuit board 2. A rear end of the bottom surface 26 of the circuit board 2 is equipped with the plurality of the first soldering pads 23 and the plurality of the second soldering pads 24. The plurality of the first soldering pads 23 and the plurality of the second soldering pads 24 of the bottom surface 26 of the circuit board 2 are disposed along a front-to-rear direction and disposed in two rows. The plurality of the first soldering pads 23 of the bottom surface 26 of the circuit board 2 are disposed behind the plurality of the second soldering pads 24 of the bottom surface 26 of the circuit board 2. A distance between the plurality of the first soldering pads 23 of the bottom surface 26 of the circuit board 2 and the tail end of the circuit board 2 is shorter than a distance between the plurality of the second soldering pads 24 of the bottom surface 26 of the circuit board 2 and the tail end of the circuit board 2.

In the first preferred embodiment, the plurality of the first soldering pads 23 of the top surface 25 of the circuit board 2 are disposed above and corresponding to the plurality of the first soldering pads 23 of the bottom surface 26 of the circuit board 2. The plurality of the second soldering pads 24 of the top surface 25 of the circuit board 2 are disposed above and corresponding to the plurality of the second soldering pads 24 of the bottom surface 26 of the circuit board 2. The first conductors 114 of the plurality of the first wire cores 111 are soldered to the plurality of the first soldering pads 23 of the top surface 25 and the bottom surface 26 of the circuit board 2, so the plurality of the first wire cores 111 are disposed in two rows along the thickness direction of the circuit board 2. The second conductors 124 of the plurality of the second wire cores 121 are soldered to the plurality of the second soldering pads 24 of the top surface 25 and the bottom surface 26 of the circuit board 2, so the plurality of the second wire cores 121 are disposed in two rows along the thickness direction of the circuit board 2.

A distance between the plurality of the first soldering pads 23 of the circuit board 2 and the tail end of the circuit board 2 is shorter than a distance between the plurality of the second soldering pads 24 of the circuit board 2 and the tail end of the circuit board 2. The circuit board 2 is disposed to and connected with one end of the cable 1. The plurality of the first wire cores 111 are disposed to inner sides of the plurality of the second wire cores 121. The plurality of the first wire cores 111 and the plurality of the second wire cores 121 of the surface of the circuit board 2 are disposed in two rows. The two rows of the first wire cores 111 are disposed to inner sides of the two rows of the second wire cores 121. The two rows of the first wire cores 111 are disposed between the two rows of the second wire cores 121.

The circuit board 2 has the board thickness compensation structure 21. In the first preferred embodiment, the board thickness compensation structure 21 is disposed on the top surface 25 of the circuit board 2. The board thickness compensation structure 21 is protruded upward from the rear end of the top surface 25 of the circuit board 2. The plurality of the second soldering pads 24 of the top surface 25 of the circuit board 2 are disposed on a surface of the board thickness compensation structure 21. The plurality of the second soldering pads 24 of the top surface 25 of the circuit board 2 are disposed on a top surface of the board thickness compensation structure 21. The second conductors 124 of one row of the second wire cores 121 are soldered to the plurality of the second soldering pads 24 of the board thickness compensation structure 21, so that a stress of the core wire group 11 being soldered to the circuit board 2 is eliminated for preventing the plurality of the second soldering pads 24 of the board thickness compensation structure 21 peeling off. In the first preferred embodiment, the board thickness compensation structure 21 is disposed on the rear end of the top surface 25 of the circuit board 2. In practice, feasibly, the board thickness compensation structure 21 is disposed to the rear end of the bottom surface 26 of the circuit board 2.

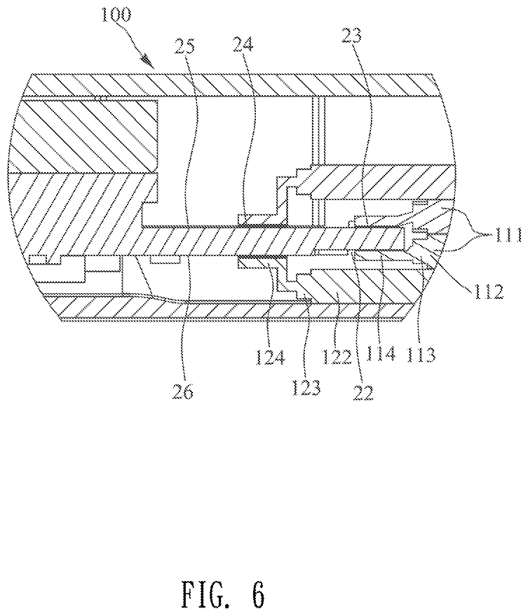

Referring to FIG. 1 to FIG. 6, the cable assembly 100 in accordance with a second preferred embodiment of the present invention is shown. Differences between the cable assembly 100 in accordance with the first preferred embodiment and the cable assembly 100 in accordance with the second preferred embodiment are described as follows. The cable assembly 100 in accordance with the second preferred embodiment includes a board thickness compensation structure 22. The board thickness compensation structure 22 is recessed in the surface of the circuit board 2. In the second preferred embodiment, the rear end of the bottom surface 26 of the circuit board 2 is recessed inward to form the board thickness compensation structure 22. The plurality of the first soldering pads 23 of the surface of the circuit board 2 are disposed to a surface of the board thickness compensation structure 22. The plurality of the first soldering pads 23 of the bottom surface 26 of the circuit board 2 are disposed to the surface of the board thickness compensation structure 22. The positions of the plurality of the second soldering pads 24 of the surface of the circuit board 2 are disposed beyond positions of the plurality of the first soldering pads 23 of the surface of the circuit board 2, so the positions of the plurality of the second wire cores 121 connected to the surface of the circuit board 2 are located beyond the positions of the plurality of the first wire cores 111 connected to the surface of the circuit board 2. The plurality of the first soldering pads 23 of the bottom surface 26 of the circuit board 2 are disposed to a surface of an inner top wall of the board thickness compensation structure 22. The first conductors 114 of one row of first wire cores 111 are soldered to the plurality of the first soldering pads 23 of the board thickness compensation structure 22, so that the stress of the core wire group 11 being soldered to the circuit board 2 is eliminated for preventing the plurality of the first soldering pads 23 of the board thickness compensation structure 22 peeling off In the second preferred embodiment, the board thickness compensation structure 22 is disposed to the bottom surface 26 of the circuit board 2. In practice, feasibly, the board thickness compensation structure 22 is disposed to the top surface 25 of the circuit board 2.

In the first preferred embodiment and the second preferred embodiment, the plurality of the second soldering pads 24 of the surface of the circuit board 2 are disposed to the surface of the board thickness compensation structure 21, or the plurality of the first soldering pads 23 of the surface of the circuit board 2 are disposed to the surface of the board thickness compensation structure 22 to make the positions of the plurality of the second soldering pads 24 of the surface of the circuit board 2 beyond the positions of the plurality of the first soldering pads 23 of the surface of the circuit board 2, so the positions of the plurality of the second wire cores 121 connected to the surface of the circuit board 2 are located beyond the positions of the plurality of the first wire cores 111 connected to the surface of the circuit board 2.

Preferably, the circuit board 2 further has a plurality of the board thickness compensation structures 21 for eliminating the stress of the the core wire group 11 being soldered to the circuit board 2. The circuit board 2 further has a plurality of the board thickness compensation structures 22 for eliminating the stress of the core wire group 11 being soldered to the circuit board 2. Thus the plurality of the board thickness compensation structures 21 and the plurality of the board thickness compensation structures 22 are without being limited within specific descriptions of the first preferred embodiment and the second preferred embodiment disclosed in the present invention.

As described above, the cable assembly 100 eliminates the stress of the core wire group 11 being soldered to the circuit board 2 by virtue of the plurality of the board thickness compensation structures 21 and the plurality of the board thickness compensation structures 22, so that the plurality of the second soldering pads 24 of the board thickness compensation structure 21 is prevented from peeling off, and the plurality of the first soldering pads 23 of the board thickness compensation structure 22 are prevented from peeling off, so the cable assembly 100 is capable of effectively lowering a mechanical stress of the circuit board 2, and the circuit board 2 of the cable assembly 100 has a lower mechanical stress. As a result, the cable assembly 100 has a cable stress lowering function.

What is claimed is:

1. A cable assembly, comprising:
a cable including a plurality of first wire cores and a plurality of second wire cores, each first wire core having a first conductor, each second wire core having a second conductor; and
a circuit board disposed to and connected with one end of the cable, a surface of the circuit board being equipped with a plurality of first soldering pads transversely arranged in one row, and a plurality of second soldering pads transversely arranged in one row and located in front of the plurality of the first soldering pads, so the plurality of the first soldering pads and the plurality of the second soldering pads of the surface of the circuit board being arranged in two rows, a distance between the plurality of the first soldering pads of the circuit board and a tail end of the circuit board being shorter than a distance between the plurality of the second soldering pads of the circuit board and the tail end of the circuit board, the first conductors of the plurality of the first wire cores being arranged in two rows along a thickness direction of the circuit board, and the second conductors of the plurality of the second wire cores being arranged in two rows along the thickness direction of the circuit board, the first conductors of the plurality of the first wire cores being connected to the plurality of the first soldering pads of the surface of the circuit board, the second conductors of the plurality of the second wire cores being connected to the plurality of the second soldering pads of the surface of the circuit board, the surface of the circuit board having a board thickness compensation structure, the plurality of the second soldering pads of the surface of the circuit board being disposed to a surface of the board thickness compensation structure,
wherein positions of the plurality of the second soldering pads of the surface of the circuit board are disposed beyond positions of the plurality of the first soldering pads of the surface of the circuit board, so positions of the plurality of the second wire cores connected to the surface of the circuit board are located beyond positions of the plurality of the first wire cores connected to the surface of the circuit board.

2. The cable assembly as claimed in claim 1, wherein the board thickness compensation structure is protruded from and projects beyond the surface of the circuit board.

3. The cable assembly as claimed in claim 1, wherein the plurality of the first wire cores are disposed in two rows along the thickness direction of the circuit board, the plurality of the second wire cores are disposed in two rows along the thickness direction of the circuit board, the two rows of the first wire cores are disposed between the two rows of the second wire cores, the circuit board has a top surface, and a bottom surface opposite to the top surface, rear ends of the top surface and the bottom surface of the circuit board are equipped with the plurality of the first soldering pads and the plurality of the second soldering pads, the first conductors of the plurality of the first wire cores are soldered to the plurality of the first soldering pads of the top surface and the bottom surface of the circuit board, the second conductors of the plurality of the second wire cores are soldered to the plurality of the second soldering pads of the top surface and the bottom surface of the circuit board.

4. The cable assembly as claimed in claim 3, wherein the board thickness compensation structure is disposed on the top surface of the circuit board.

5. The cable assembly as claimed in claim 3, wherein the board thickness compensation structure is protruded upward from the rear end of the top surface of the circuit board.

6. The cable assembly as claimed in claim 3, wherein the board thickness compensation structure is recessed in and disposed to the top surface of the circuit board.

7. The cable assembly as claimed in claim 3, wherein the surface of the circuit board is one of the top surface and the bottom surface of the circuit board.

8. The cable assembly as claimed in claim 3, wherein a rear end of the bottom surface of the circuit board is recessed inward to form the thickness compensation structure, the plurality of the first soldering pads of the bottom surface of the circuit board are disposed to a surface of an inner top wall of the board thickness compensation structure, the first conductors of one row of the first wire cores are soldered to the plurality of the first soldering pads of the board thickness compensation structure.

9. The cable assembly as claimed in claim 1, wherein the plurality of the first wire cores are disposed in two rows along the thickness direction of the circuit board, the plurality of the second wire cores are disposed in two rows along the thickness direction of the circuit board.

10. A cable assembly, comprising:
a cable including a plurality of first wire cores and a plurality of second wire cores, each first wire core having a first conductor, each second wire core having a second conductor; and
a circuit board disposed to and connected with one end of the cable, a surface of the circuit board being equipped with a plurality of first soldering pads transversely arranged in one row, and a plurality of second soldering pads transversely arranged in one row, so the plurality of the first soldering pads and the plurality of the second soldering pads of the surface of the circuit board being arranged in two rows, a distance between the plurality of the first soldering pads of the circuit board and a tail end of the circuit board being shorter than a distance between the plurality of the second soldering pads of the circuit board and the tail end of the circuit board, the first conductors of the plurality of the first wire cores being arranged in two rows along a thickness direction of the circuit board, and the second conductors of the plurality of the second wire cores being arranged in two rows along the thickness direction of the circuit board, the first conductors of the plurality of the first wire cores being connected to the plurality of the first soldering pads of the surface of the circuit board, the second conductors of the plurality of the second wire cores being connected to the plurality of the second soldering pads of the surface of the circuit board, the circuit board having a board thickness compensation structure, the plurality of the first soldering pads of the surface of the circuit board being disposed to a surface of the board thickness compensation structure,
wherein positions of the plurality of the second soldering pads of the surface of the circuit board are disposed beyond positions of the plurality of the first soldering pads of the surface of the circuit board, so positions of the plurality of the second wire cores connected to the surface of the circuit board are located beyond positions of the plurality of the first wire cores connected to the surface of the circuit board.

11. The cable assembly as claimed in claim 10, wherein the board thickness compensation structure is recessed in the surface of the circuit board.

12. The cable assembly as claimed in claim 10, wherein the plurality of the first wire cores are disposed in two rows along the thickness direction of the circuit board, the plurality of the second wire cores are disposed in two rows along the thickness direction of the circuit board, the two rows of the first wire cores are disposed between the two rows of the second wire cores, the circuit board has a top surface, and a bottom surface opposite to the top surface, rear ends of the top surface and the bottom surface of the circuit board are equipped with the plurality of the first soldering pads and the plurality of the second soldering pads, the first conductors of the plurality of the first wire cores are soldered to the plurality of the first soldering pads of the top surface and the bottom surface of the circuit board, the second conductors of the plurality of the second wire cores are soldered to the plurality of the second soldering pads of the top surface and the bottom surface of the circuit board.

13. The cable assembly as claimed in claim 12, wherein the board thickness compensation structure is disposed to the rear end of the bottom surface of the circuit board.

14. The cable assembly as claimed in claim 12, wherein a rear end of the bottom surface of the circuit board is recessed inward to form the thickness compensation structure, the plurality of the first soldering pads of the bottom surface of the circuit board are disposed to a surface of an inner top wall of the thickness compensation structure, the first conductors of one row of the first wire cores are soldered to the plurality of the first soldering pads of the board thickness compensation structure.

15. The cable assembly as claimed in claim 12, wherein the thickness compensation structure is recessed in and disposed to the top surface of the circuit board.

16. The cable assembly as claimed in claim 12, wherein the surface of the circuit board is one of the top surface and the bottom surface of the circuit board.

17. The cable assembly as claimed in claim 12, wherein the board thickness compensation structure is protruded upward from the rear end of the top surface of the circuit board.

18. The cable assembly as claimed in claim 10, wherein the board thickness compensation structure is protruded from and projects beyond the surface of the circuit board.

19. The cable assembly as claimed in claim 10, wherein the plurality of the first wire cores are disposed in two rows along the thickness direction of the circuit board, the plurality of the second wire cores are disposed in two rows along the thickness direction of the circuit board.

20. A cable assembly, comprising:
a cable including a plurality of first wire cores and a plurality of second wire cores, each first wire core having a first conductor, each second wire core having a second conductor;
a circuit board connected with one end of the cable, a surface of the circuit board being equipped with a plurality of first soldering pads transversely arranged in one row, and a plurality of second soldering pads transversely arranged in one row and located in front of the plurality of the first soldering pads, so the plurality of the first soldering pads and the plurality of the second soldering pads of the surface of the circuit board being arranged in two rows, the first conductors of the plurality of the first wire cores being arranged in two rows along a thickness direction of the circuit board, and the second conductors of the plurality of the second wire cores being arranged in two rows along the thickness direction of the circuit board, the first conductors of the plurality of the first wire cores being soldered to the plurality of the first soldering pads of the surface of the circuit board, the second conductors of the plurality of the second wire cores being soldered to the plurality of the second soldering pads of the surface of the circuit board, the surface of the circuit board having a board thickness compensation structure, the plurality of the second soldering pads of the surface of the circuit board being disposed to the surface of the board thickness compensation structure, or the plurality of the first soldering pads of the surface of the circuit board being disposed to the surface of the board thickness compensation structure to make positions of the plurality of the second soldering pads of the surface of the circuit board beyond positions of the plurality of the first soldering pads of the surface of the circuit board, so positions of the plurality of the second wire cores connected to the surface of the circuit board are located beyond positions of the plurality of the first wire cores connected to the surface of the circuit board;
a heat dissipating module disposed on the circuit board; and
an outer cover surrounding the circuit board, the heat dissipating module and the cable.
